(19) United States
(12) Patent Application Publication
(10) Pub. No.: US 2025/0306299 A1
(43) Pub. Date: Oct. 2, 2025

(54) CARRIER-MODULATED WAVEGUIDE STRUCTURE

(71) Applicant: YUAN ZE UNIVERSITY, Taoyuan City (TW)

(72) Inventors: Jau-Yang Wu, Hsinchu County (TW); Gong-Ru Lin, Taipei City (TW); Ding-Wei Huang, Taipei City (TW)

(21) Appl. No.: 18/659,030

(22) Filed: May 9, 2024

(30) Foreign Application Priority Data
Apr. 1, 2024 (TW) 113112398

(51) Int. Cl. G02B 6/42; G02B 6/12

(52) U.S. Cl. CPC G02B 6/4207; G02B 2006/12123; G02B 2006/12126; G02B 2006/12138

(57) ABSTRACT

A carrier-modulated waveguide structure which comprises a semiconductor bias unit, a light absorbing component, and a transporting control element is provided. The light absorbing component is disposed over a part of the semiconductor bias unit and the transporting control element is arranged at one side of both the semiconductor bias unit and the light absorbing component and connected with the side of the light absorbing component. The transporting control element comprises a main body. One side of the main body is connected with the light absorbing component and another side of the main body is provided with a plurality of carrier channels spaced apart from one another. The plurality of carrier channels is connected with a plurality of light sensors correspondingly. Thereby difference in detection probability and dead period of single photon avalanche diodes can be overcome by the carrier channels conducted due to electrical field for photon detection.

### FIELD OF THE INVENTION

The present invention relates to a waveguide, especially to a carrier-modulated waveguide structure.

### BACKGROUND OF THE INVENTION

Owing to fast development of modern technology, electronic devices (such as mobile phone and tablets) are closely related to our lives or works. Most of modern electronic devices are equipped with various types of sensors, such as proximity sensors, ambient light sensors, temperature sensors, etc., as auxiliary equipment for the electronic devices to provide various functional abilities, such as reducing radio frequency power when a person is close to the electronic device, adjusting screen brightness according to ambient brightness automatically, or adjusting operation modes according to temperature of the electronic device.

Along with development of modern technology, electronic devices have more versatile designs and applications according to our living needs. In order to improve safety, convenience, and entertainment of life, range detection technology, such as Time of Flight (ToF) plays an indispensable role.

The Time of Flight which executes ranging detection by using optical sensors which receives and converts optical signals into electrical signals to output the electrical signals. The optical sensor commonly used in the industry art is a Single Photon Avalanche Diode (SPAD) which is an optical ranging detection with high sensitivity and thus able to detect a single photon. After being triggered by the photon, the voltage level of the SPAD is returned to its original value by quench and recharging and ready for the next triggering of photon.

Under strong ambient light, the SPAD available now may be unable to sense the incident photons and output corresponding sensing signals. This is called blinding condition. Yet SPAD with passive quench/recharge circuit now has charge and discharge current which is lower than latching current for prevention of latch. It takes quite a long time from being triggered by photons to completion of recharging through quenching so that the deadtime of the SPAD is long and dynamic range of the SPAD is low. Under strong ambient light, the SPAD with passive quench/recharge circuit is easier to have multi-trigger problem. Thus the SPAD with passive quench/recharge circuit is unable to detect the incident photons and output corresponding sensing signals within a long period. Thus the optical sensing efficiency of the SPAD with passive quench/recharge circuit available now is lower.

Among techniques available now, a SPAD can be controlled by a gate bias or a direct current bias. However, upon detecting a photon, the SPAD needs pass a dead time to return to the active state again for sensing the next photon continuously. The SPAD is unable to detect photons during the dead time and this leads to signal loss.

Thus, there is room for improvement and there is a need to provide a carrier-modulated waveguide structure in order to solve the above problems.

### SUMMARY

Therefore, a primary object of the present invention is to provide a carrier-modulated waveguide structure which includes a main body of a transporting control element provided with a plurality of carrier channels extending outward and a light absorbing component connected with a plurality of light sensors through the main body and the carrier channels for reducing effects of a dead period on detection of incident photons and improving light sensing accuracy. Moreover, an absorption layer in which light is incident from the front side or lateral side is designed and provided for different applications.

Another object of the present invention is to provide a carrier-modulated waveguide structure which includes a main body of a transporting control element provided with a plurality of carrier channels extending outward and a light absorbing component connected with a plurality of light sensors through the main body and the carrier channels. In combination with a larger absorption layer, a design of a photon number resolving detector (PNRD) with uniformity and high performance can be achieved.

A further object of the present invention is to provide a carrier-modulated waveguide structure which includes a main body of a transporting control element provided with a plurality of carrier channels extending outward for compensation of difference in detection probabilities of components in an array by compensation of different amounts of electric field.

In order to achieve the above objects, a carrier-modulated waveguide structure according to the present invention is provided and includes a semiconductor bias unit, a light absorbing component, and a transporting control element. The semiconductor bias unit comprising a first semiconductor layer, a bias intrinsic layer, and a second semiconductor layer. The first semiconductor layer and the second semiconductor layer are correspondingly disposed on two opposite sides of the bias intrinsic layer. The light absorbing component is mounted over a part of the first semiconductor layer, the bias intrinsic layer, and a part of the second semiconductor layer. The transporting control element is disposed on one side of the light absorbing component. The transporting control element comprises a main body. One side of the main body is connected with the light absorbing component and another side of the main body is provided with a plurality of carrier channels spaced apart from one another. The plurality of carrier channels is connected with a plurality of light sensors correspondingly. That means the carrier-channels are disposed on and extending from the main body toward a direction without connection to the light absorbing component for connection with the light sensors. The sum of a probability of carrier transport of the respective carrier channels is 1. The effect of a dead period on detection of other incident photons is reduced by the transporting control element. Moreover, detection of incident photons in different directions can be carried out.

Preferably, the first semiconductor layer and the second semiconductor layer are a p-type semiconductor layer and a n-type semiconductor layer respectively. The light absorbing component is a germanium component, and a material for the transporting control element is selected from a p-type silicon material.

Preferably, the first semiconductor layer and the second semiconductor layer are respectively provided with a first protrusion and a second protrusion. The light absorbing component is disposed over the first protrusion and the second protrusion. A first semiconductor doped layer and a second semiconductor doped layer are respectively connected to an outer side of the first semiconductor layer and an outer side of the second semiconductor layer.

The respective light sensors consist of a first electrode, a first semiconductor bias layer, a sensing intrinsic layer, a second semiconductor bias layer, and a second electrode. The first semiconductor bias layer is connected to the first electrode and the sensing intrinsic layer is connected to one side of the first semiconductor bias layer. The second semiconductor bias layer is connected to one side of the sensing intrinsic layer and the second electrode is connected to one side of the second semiconductor bias layer. The sensing intrinsic layers of the light sensors are connected to the carrier channels.

Preferably, the carrier-modulated waveguide structure further includes a gate bias component which is electrically connected to and located over the light absorbing component and providing a gate bias to the light absorbing component.

Preferably, when a first light sensor of the light sensors receives a first incident photon which is absorbed by the light absorbing component from the transporting control element, the first light sensor drives a first carrier channel among the carrier channels and corresponding to the first light sensor to close and generates a light sensing signal within a first dead period. Difference in detection probabilities of components in an array is compensated by compensation of different amounts of electric field.

Preferably, when at least one light sensor of the light sensors receives at least one incident photon which is absorbed by the light absorbing component from the transporting control element, the at least one light sensor drives at least one carrier channel among the carrier channels and corresponding to the at least one light sensor to close and generates a quantum strength signal according to the at least one incident photon within a first dead period. The number of the at least one incident photon determines strength of the quantum strength signal to achieve a design of a photon number resolving detector (PNRD) with uniformity and high performance.

### BRIEF DESCRIPTION OF THE DRAWINGS

FIG. 1A is a schematic drawing showing structure of a carrier-modulated waveguide structure of an embodiment according to the present invention;

FIG. 1B is a schematic drawing showing detection of an incident light by an embodiment according to the present invention;

FIG. 2 is a schematic drawing showing structure of a light sensor of an embodiment according to the present invention;

FIG. 3 is a schematic drawing showing a semiconductor bias unit of an embodiment according to the present invention;

FIG. 4 is a schematic drawing showing signals during detection of incident photons of an embodiment according to the present invention;

FIG. 5 is a schematic drawing showing signals during detection of incident photons of another embodiment according to the present invention;

FIG. 6 is a schematic drawing showing signals during detection of incident photons of a further embodiment according to the present invention;

FIG. 7 is a schematic drawing showing structure of a light sensor of another embodiment according to the present invention;

FIG. 8A is a schematic drawing showing structure of a carrier-modulated waveguide structure of another embodiment according to the present invention;

FIG. 8B is a schematic drawing showing detection of an incident light by another embodiment according to the present invention;

FIG. 9 is a schematic drawing showing signals during detection of incident photons of a further (another) embodiment according to the present invention;

FIG. 10 is a schematic drawing showing signals during detection of incident photons of a further (another) embodiment according to the present invention;

FIG. 11 is a schematic drawing showing signals during detection of incident photons of a further (another) embodiment according to the present invention.

### DETAILED DESCRIPTION

In order to learn features and functions of the present invention more clearly, please refer to the following embodiments and detailed description.

Certain terms are used in the description and claims to refer to particular elements. Those skilled in the art should understand that hardware manufacturers may use different terms to refer to the same component. The specification and claims do not use the difference in name as a way to distinguish components, but use the difference in function of components as a criterion for distinguishing. “Includes” mentioned throughout the specification and claims is an open term, so it should be interpreted as “including but not limited to”. In addition, the term “coupled” herein includes any direct and indirect means of connection. Therefore, if it is described that a first device is coupled to a second device, it means that the first device may be directly connected to the second device, or indirectly connected to the second device through other devices or connection means.

The light sensors available now often have problems in detection of incident photons during the dead period. Thereby the present invention provides a carrier-modulated waveguide structure which uses a transporting control element to control and transport incident photons received by a light absorbing component to one of a plurality of carrier channels and further to a light sensor connected with the carrier channel to solve reduce effects of the dead period on detection of the incident photons and improve light sensing accuracy. Moreover, an absorption layer in which light is incident from the front side or lateral side is designed and provided for different applications. The present carrier-modulated waveguide structure can also be applied to a design of a photon number resolving detector (PNRD) with uniformity and high performance as well as compensation of difference in detection probabilities of components by compensation of different amounts of electric field.

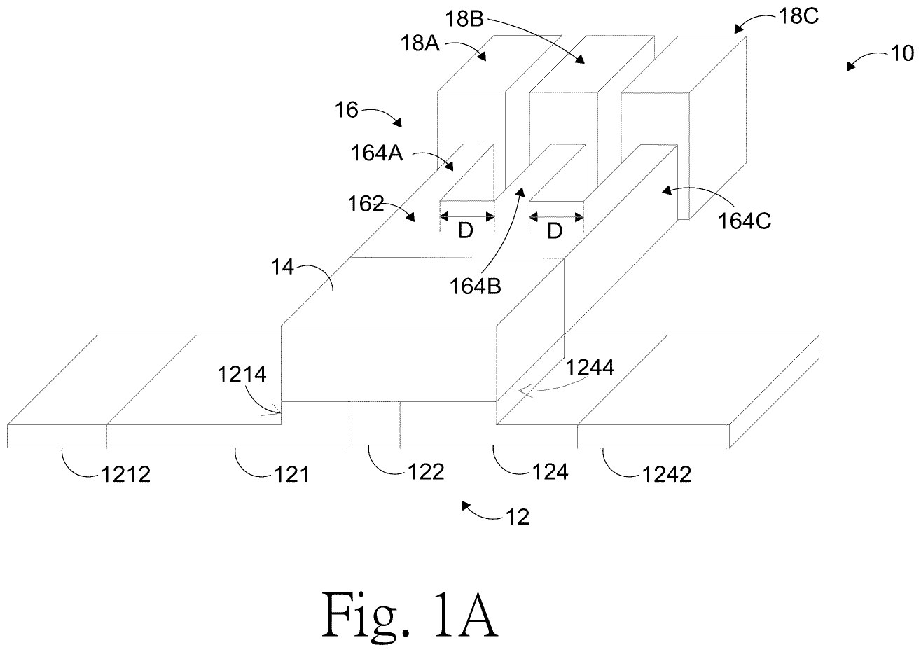

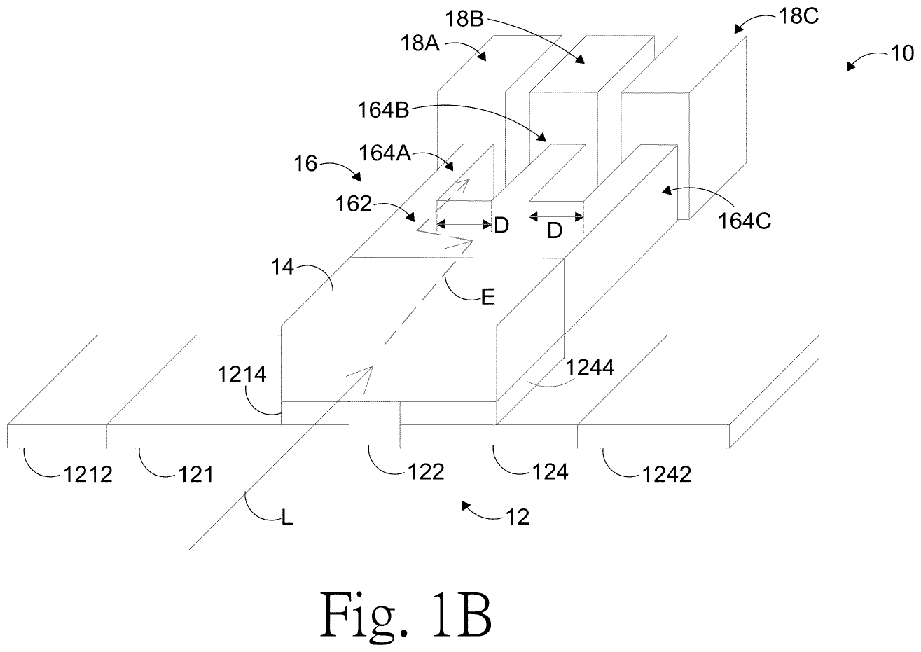

Refer to FIG. 1A, a schematic drawing showing structure of an embodiment of a carrier-modulated waveguide structure is provided. In this embodiment, a carrier-modulated waveguide structure 10 according to the present invention is applied to smart mobile phones, tablet computers, or other consumer electronics and comprises a semiconductor bias unit 12, a light absorbing component 14, and a transporting control element 16. The semiconductor bias unit 12 includes a first semiconductor layer 121, a bias intrinsic layer 122, and a second semiconductor layer 124. In this embodiment, the first semiconductor layer 121 and the second semiconductor layer 124 are correspondingly disposed on two opposite sides of the bias intrinsic layer 122. A height of a part of the first semiconductor layer 121 and a height of a part of the second semiconductor layer 124 are the same as a height of the bias intrinsic layer 122 so as to form a stacked platform while the light absorbing component 14 is arranged over a part of the semiconductor bias unit 12 and located over the bias intrinsic layer 122. That means the light absorbing component 14 is mounted over the part of the first semiconductor layer 121, the bias intrinsic layer 122, and the part of the second semiconductor layer 124. The light absorbing component 14 is disposed on the stacked platform. As to the transporting control element 16, it is arranged at one side of both the semiconductor bias unit 12 and the light absorbing component 14 and connected with the side of the light absorbing component 14. In this embodiment, the first semiconductor layer 121 and the second semiconductor layer 124 are a p-type semiconductor layer and a n-type semiconductor layer respectively. Material for the light absorbing component 14 is selected from germanium, that is, the light absorbing component 14 is a germanium component. A material for the transporting control element 16 is selected from p-type silicon material.

The transporting control element 16 comprises a main body 162 and a plurality of carrier channels spaced apart from one another. That means there is an interval (distance) between two adjacent carrier channels. One side of the main body 162 is connected with the light absorbing component 14 and another side of the main body 162 is provided with the plurality of the carrier channels. In this embodiment, as an example, a first carrier channel 164A, a second carrier channel 164B, and a third carrier channel 164C are arranged at and extending from the another side of the transporting control element 16. An interval (distance) D is formed between two of the first carrier channel 164A, the second carrier channel 164B, and the third carrier channel 164C adjacent to each other. The interval (distance) D can be the same or different from each other. The carrier channels are connected with a plurality of light sensors. The carrier-channels are disposed on and extending from the main body 162 toward a direction without connection to the light absorbing component 14 for connection with the light sensors. The sum of probabilities of carrier transport of all the carrier channels is 1. Thus whether the probabilities the respective light sensors receive carriers are the same or not depends on a bias of the respective light sensors applied to the corresponding carrier channels. In this embodiment, a first light sensor 18A, a second light sensor 18B, and a third light sensor 18C are taken as examples of the light sensors. In this embodiment, probabilities of carrier transport of the first carrier channel 164A, the second carrier channel 164B, and the third carrier channel 164C are all one-third (⅓) while probabilities the first light sensor 18A, the second light sensor 18B, and the third light sensor 18C respectively receive the carriers are also one third (⅓). As shown in FIG. 1B, the light absorbing component 14 receives and converts an incident light L into photoelectrons E. Then the photoelectrons E are output to the transporting control element 16 and transported to one of the carrier channels according to the probability of carrier transport for allowing the corresponding light sensor to receive and sense the photoelectrons E.

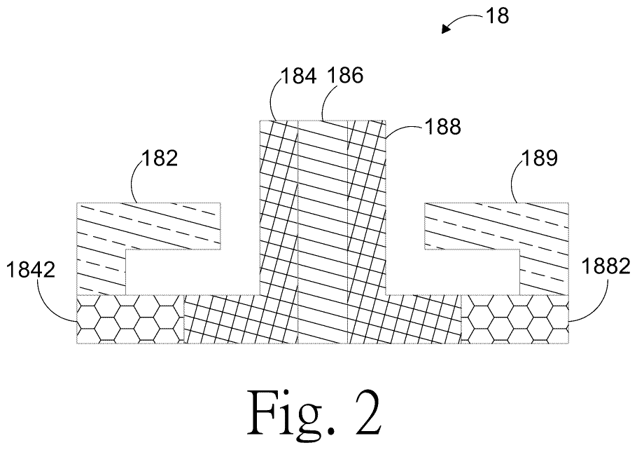

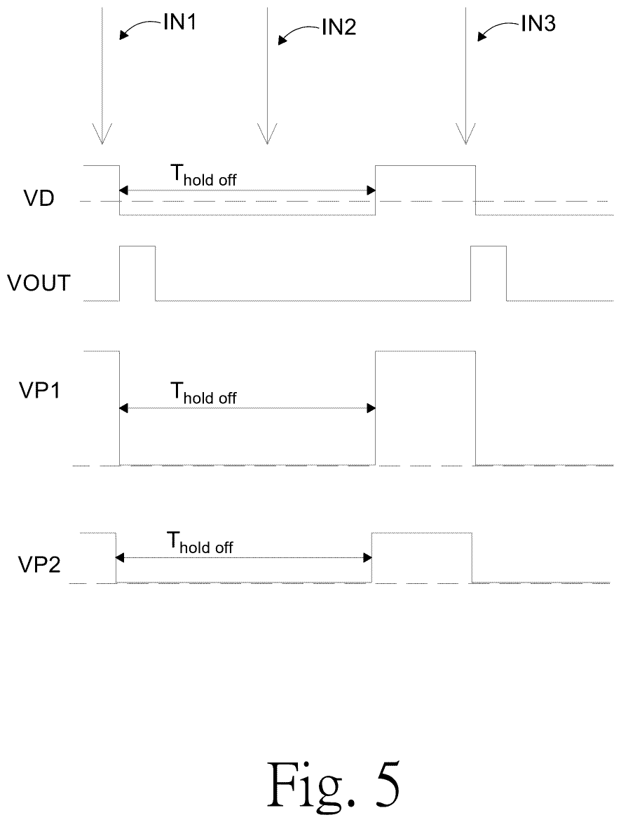

Refer to FIG. 2, a schematic drawing showing structure of a light sensor of an embodiment according to the present invention is provided. As shown in figure, a light sensor 18 is equal to the first light sensor 18A, the second light sensor 18B, and the third light sensor 18C of the above embodiment. The light sensor 18 comprising a first electrode 182, a first semiconductor bias layer 184, a sensing intrinsic layer 186, a second semiconductor bias layer 188, and a second electrode 189. The first semiconductor bias layer 184 is disposed on one side of the first electrode 182 and coupled to the first electrode 182. The sensing intrinsic layer 186 is arranged at one side of the first semiconductor bias layer 184 and connected to the first semiconductor bias layer 184. The second semiconductor bias layer 188 is mounted to one side of the sensing intrinsic layer 186 and connected to the sensing intrinsic layer 186. The second electrode 189 is disposed on one side of the second semiconductor bias layer 188 and coupled to the second semiconductor bias layer 188. The sensing intrinsic layers 186 of the light sensors are connected to the carrier channels. For example, the sensing intrinsic layers 186 of the first light sensor 18A, the second light sensor 18B, and the third light sensor 18C are connected to the first carrier channel 164A, the second carrier channel 164B, and the third carrier channel 164C correspondingly in a one-to-one manner. That means the first light sensor 18A, the second light sensor 18B, and the third light sensor 18C apply a bias, a waveguide bias VP (as shown in FIG. 5), to the corresponding carrier channels by the first semiconductor bias layer 184 and the second semiconductor bias layer 188. Moreover, the first semiconductor bias layer 184 and the second semiconductor bias layer 188 are respectively provided with a first doped bias layer 1842 for connection with the first electrode 182 and a second doped bias layer 1882 extending outward for connection with the second electrode 189 correspondingly.

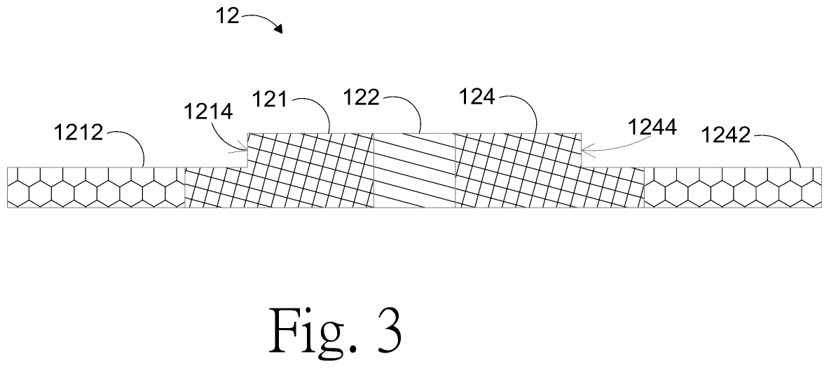

Refer to FIG. 1A and FIG. 3 which is a schematic drawing of a semiconductor bias unit of an embodiment, the semiconductor bias unit 12 in FIG. 3 includes the first semiconductor layer 121, the bias intrinsic layer 122, and the second semiconductor layer 124. In this embodiment, the first semiconductor layer 121 and the second semiconductor layer 124 are disposed on two opposite sides of the bias intrinsic layer 122. A first semiconductor doped layer 1212 is extending from the first semiconductor layer 121 toward a direction opposite to the side of the first semiconductor layer 121 connected with the bias intrinsic layer 122 and a first protrusion 1214 is arranged at and projecting from the first semiconductor layer 121. Similarly, a second semiconductor doped layer 1242 is extending from the second semiconductor layer 124 toward a direction opposite to the side of the second semiconductor layer 124 connected with the bias intrinsic layer 122 and a second protrusion 1244 is arranged at and projecting from the second semiconductor layer 124. The first protrusion 1214 and the second protrusion 1244 are combined with the bias intrinsic layer 122 to form the stacked platform which is used for arrangement of the light absorbing component 14. For example, germanium is deposited on the stacked platform by physical vapor deposition (PVD) or chemical vapor deposition (CVD) so as to form the light absorbing component 14 over the stacked platform. Thereby a component bias VD (as shown in FIG. 5) is provided to the light absorbing component 14. In this embodiment, the first semiconductor layer 121 and the second semiconductor layer 124 are respectively a p-type semiconductor layer and a n-type semiconductor layer. The first semiconductor doped layer 1212 and the second semiconductor doped layer 1242 are respectively a p-type doped layer and a n-type doped layer.

Refer to FIG. 1B, take an incident light L that is emitted into the light absorbing component 14 and converted into the photoelectrons E as an example. The semiconductor bias unit 12 provides a component bias VD to the light absorbing component 14 so that the light absorbing component 14 receives the incident light L and converts at least one photon included in the incident light L into at least one photoelectron E under control of the semiconductor bias unit 12. In this embodiment, the light absorbing component 14 can sense the incident light L which is a light with a wavelength of 1550 nm. Moreover, the light absorbing component 14 can sense a light with a wavelength ranging from 850 nm to 1700 nm.

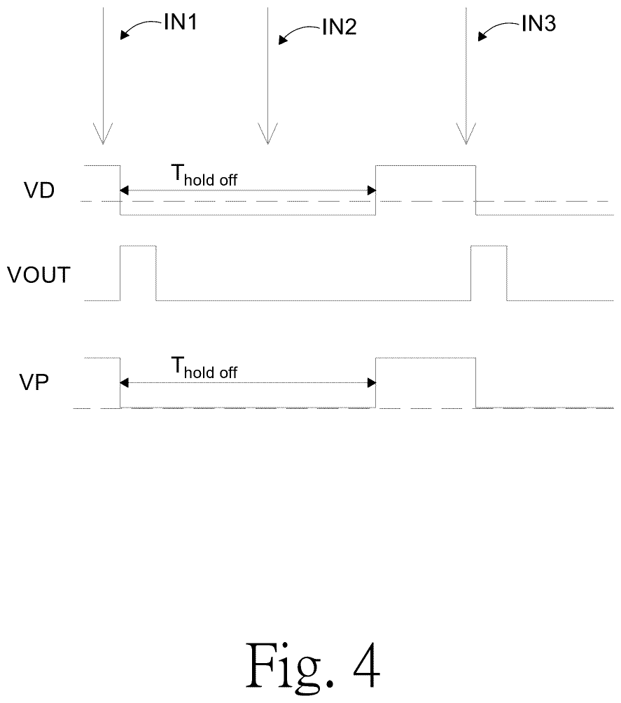

Refer to FIG. 1B and FIG. 4 which is a schematic drawing showing signals of incident photons of an embodiment according to the present invention. The photoelectron E is driven by the component bias VD to flow from the light absorbing component 14 to the transporting control element 16. The photoelectron E is transported to one of the first carrier channel 164A, the second carrier channel 164B, and the third carrier channel 164C under influence of the bias provided by the first light sensor 18A, the second light sensor 18B, and the third light sensor 18C. With respect to the component bias VD, the waveguide bias VP provided from the first light sensor 18A, the second light sensor 18B, and the third light sensor 18C to the first carrier channel 164A, the second carrier channel 164B, and the third carrier channel 164C forms the electric fields mentioned above. Under influence of the electric field, the photoelectron E is transported randomly to one of the first carrier channel 164A, the second carrier channel 164B, and the third carrier channel 164C. In this embodiment, use the photoelectron E transported to the first carrier channel 164A as an example, but not limited. Along with the probability, the photoelectron E may be transported to second carrier channel 164B or the third carrier channel 164C.

While the first light sensor 18A receiving the photoelectron E to which a first incident photon IN1 corresponds, the first light sensor 18A enters a dead period T_{hold off} during which the first light sensor 18A is incapable of working. That's a static state. After receiving the photoelectron E to which a first incident photon IN1 corresponds, the first light sensor 18A generates an output signal VOUT after a delay period correspondingly. Thereby during the dead period T_{hold off}, the first light sensor 18A will not react in response to other incident photons such as producing the output signal VOUT. During the dead period T_{hold off} of the first light sensor 18A, the light absorbing component 14 receives another incident photon. For example, a second incident photon IN2 is emitted into the light absorbing component 14 and converted into the photoelectron E of the second incident photon IN2. The light absorbing component 14 is unable to transport the photoelectron E of the second incident photon IN2 to the first light sensor 18A through the transporting control element 16. At the moment, only the second light sensor 18B and the third light sensor 18C can detect the photons. Thus the possibility the second light sensor 18B and the third light sensor 18C receive the photoelectron E of the second incident photon IN2 is both one half. Thereby the photoelectron E corresponding to the second incident photon IN2 is transported to the second carrier channel 164B or the third carrier channel 164C through the transporting control element 16 to be received by the second light sensor 18B, or the third light sensor 18C.

After the dead period T_{hold off} ended, the first light sensor 18A continues to detect the next incident photon such as a third incident photon IN3.

Refer to FIG. 5, a schematic drawing showing signals during detection of incident photons of another embodiment according to the present invention is provided. The difference between the embodiments in FIG. 4 and FIG. 5 is in that different biases are provided to light sensors with different detection probabilities in the embodiment shown in FIG. 5. For example, the light sensors are respectively provided with a first waveguide bias VP1 and a second waveguide bias VP2 while the first waveguide bias VP1 is larger than the second waveguide bias VP2. The rest parts of the embodiment in FIG. 5 are the same as those of the embodiment in FIG. 4 and not repeated herein.

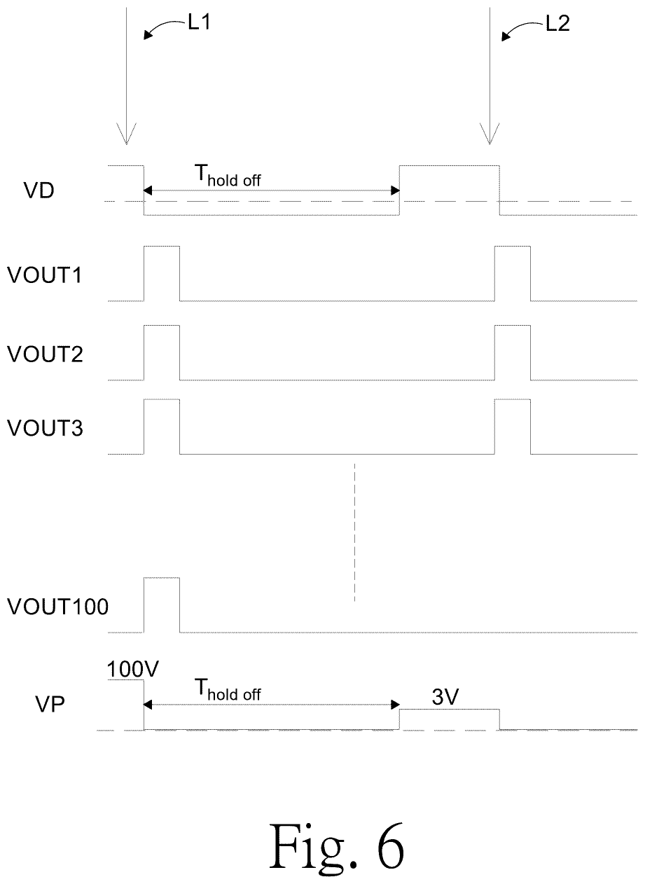

Refer to FIG. 6, a schematic drawing showing signals during detection of incident photons of a further embodiment according to the present invention is provided. The difference between the embodiments in FIG. 5 and FIG. 6 is in that different biases are provided to the light sensors with different detection probabilities for detection of different incident photons in the embodiment shown in FIG. 5 while light sensors are used to detect the number of photons in the embodiment in FIG. 6. For example, a plurality of light sensors is used to detect output signals of different incident light in FIG. 6. Thereby there is a single output signal VOUT shown in FIG. 5 while there is a plurality of output signals VOUT1˜VOUT100 shown in FIG. 6. In FIG. 6, the output signals ranging from the first output signal VOUT1 to the hundredth output signal VOUT100 are taken as an example.

In the present carrier-modulated waveguide structure 10, a plurality of carrier channels is connected to a plurality of light sensors. In this embodiment (FIG. 6), 100 carrier channels are connected to 100 light sensors and used as an example. The number of photons of a first incident light L1 and a second incident light L2 are respectively 100 and 3. As an example, an incident light received by the light absorbing component 14 includes at least one photon. The output signals provided by the present carrier-modulated waveguide structure 10 ranging from the first output signal VOUT1 to the hundredth output signal VOUT100 are all at high level and this means the number of the photons included in the incident light is 100. Thus within allowable range, the number of the photons included in the first incident light L1 and the second incident light L2 which are respectively 100 and 3 can be used as encryption for light communication. The same optical signal can use different numbers of photons to represent different quantum strength so that the following processing circuit (not shown in figure) can perform decryption of the optical signal by look-up table or preset values. Within the allowable range of the carrier-modulated waveguide structure 10 according to the present invention, 256 carrier channels are provided for connection with 256 light sensors. Thereby not only the number of photons can be switched among the range of 0-100 for encryption, the effects of the dead period T_{hold off} on detection of the incident photons can be avoided.

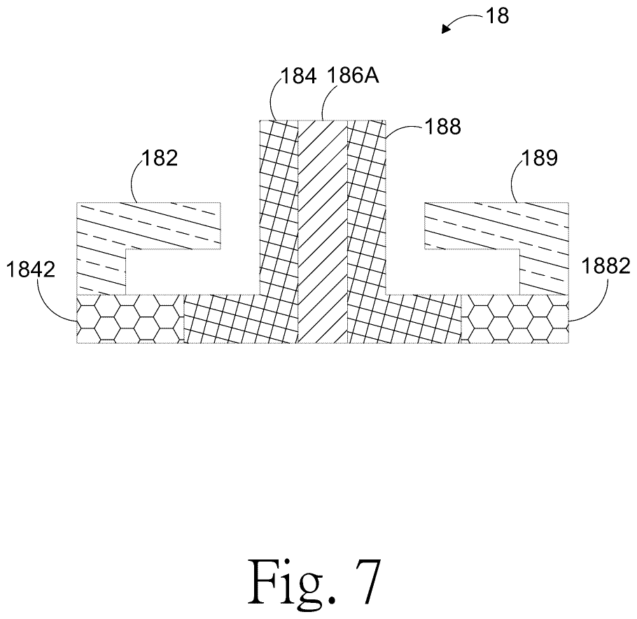

Refer to FIG. 7, a schematic drawing showing structure of a light sensor of another embodiment according to the present invention is provided. The embodiments in FIG. 2 and FIG. 7 are different in that the sensing intrinsic layer 186 of the embodiment in FIG. 2 is an intrinsic layer yet the sensing intrinsic layer 186A of the embodiment in FIG. 7 is a silicon semiconductor layer. The rest parts of the embodiment in FIG. 7 are the same as those of the embodiment in FIG. 2 and not repeated herein.

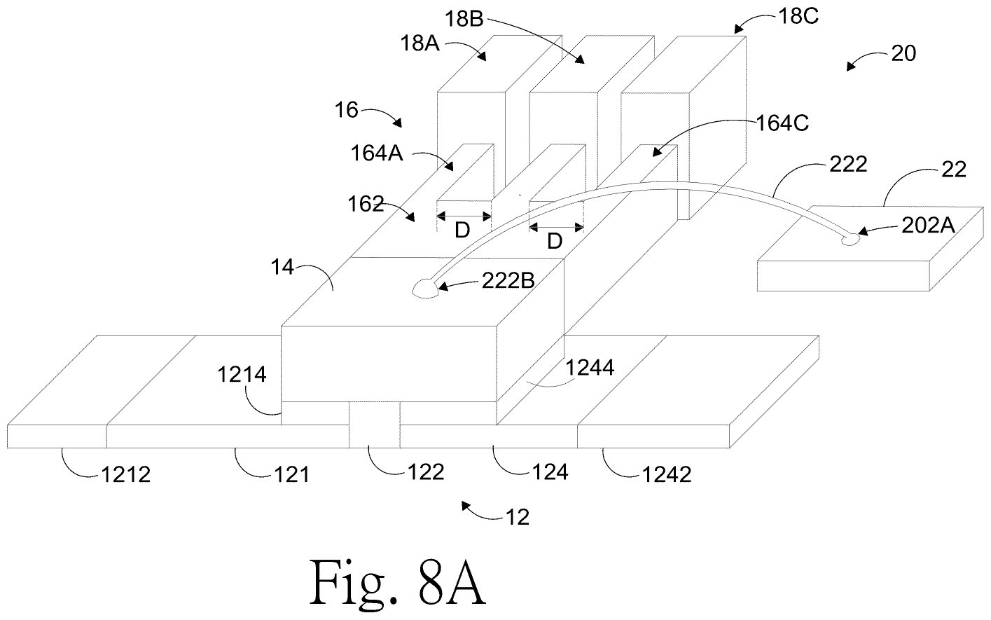

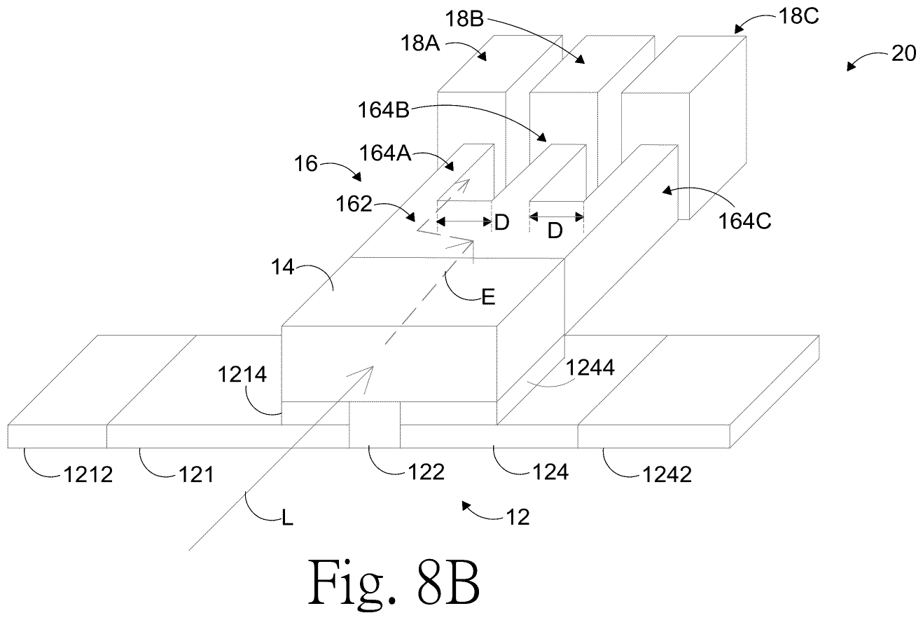

Refer to FIG. 8A and FIG. 8B, a schematic drawing showing structure of a carrier-modulated waveguide structure of another embodiment according to the present invention is provided. The difference between the embodiment shown in FIG. 1A and FIG. 1B and the embodiment shown in FIG. 8A and FIG. 8B is in that the embodiment in FIG. 8A and FIG. 8B is further provided with a gate electrode 22 which is served as a gate bias component connected to the light absorbing component 14 by a gate wire 222. As shown in FIG. 8A and FIG. 8B, the gate wire 222 makes connection between the light absorbing component 14 and the gate electrode 22 by wire-bonding. The gate wire 222 includes a first wire-bonding portion 222A and a second wire-bonding portion 222B respectively arranged at the gate electrode 22 and the light absorbing component 14.

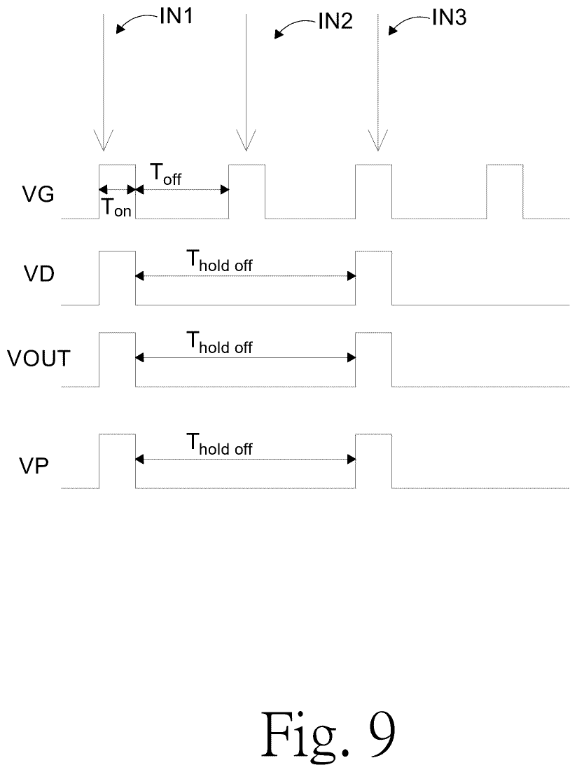

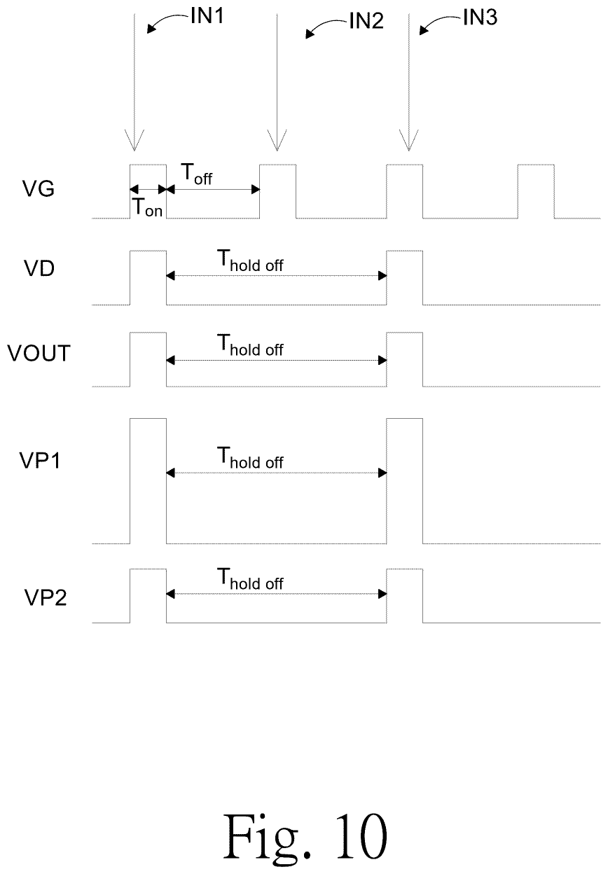

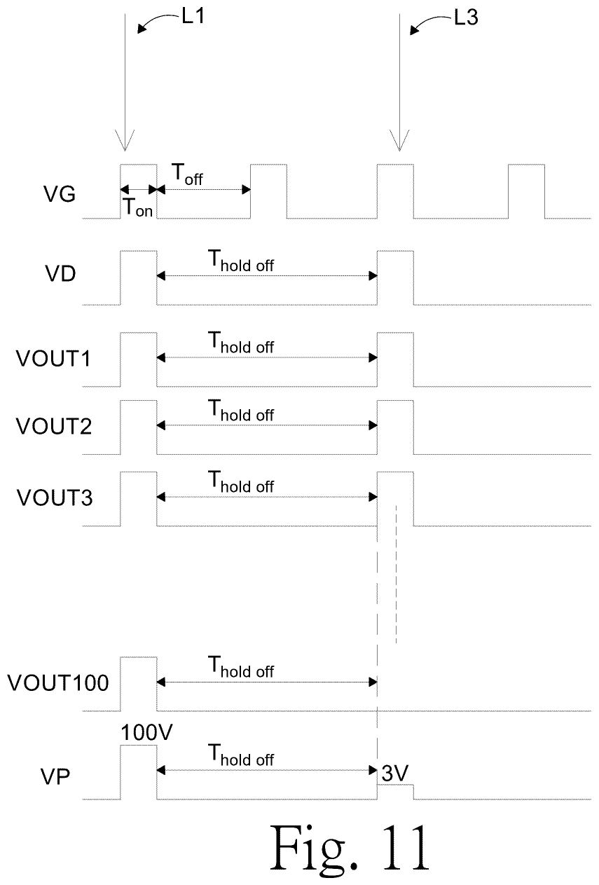

Refer to FIG. 9-11, further embodiments are provided. The difference between the embodiments in FIG. 4-6 and the embodiments in FIG. 9-11 is in that the embodiments in FIG. 9-11 further include a gate bias VG which is transferred from the gate electrode 22 and the gate wire 222 to the light absorbing component 14, such as timing controller, power supply or power controller or power IC supplying the gate bias VG to the gate electrode 22 for transferring to the light absorbing component 14. Under control of the gate bias VG, the light absorbing component 14 provides the corresponding photoelectrons E according to the incident light L. Then the corresponding light sensors generates the output signal VOUT and the first to the hundredth output signals VOUT1-VOUT100. For the gate bias VG, an on-period Tₒₙ is longer than an off-period T_{off}. The rest parts of this embodiment are the same as those of the embodiment in FIG. 4-6 and not repeated herein.

In summary, a carrier-modulated waveguide structure according to the present invention includes a semiconductor bias unit, a light absorbing component, and a transporting control element. The semiconductor bias unit provides a component bias to the light absorbing component. Then the light absorbing component converts at least one incident photon included in an incident light into at least one photoelectron according to the component bias received. Next the photoelectron is sent to a plurality of light sensors through a plurality of carrier channels arranged at a main body of the transporting control element and connected with the light sensors. After at least one of the light sensors receiving the photoelectron, the light sensor enters a dead period while the rest of the carrier channels continue transport photoelectrons corresponding to the following incident photons to the rest light sensors for detection of another incident light or another incident photon. Therefore, effects of the dead period on detection of the photons can be avoided. Moreover, the carrier-modulated waveguide structure can also be applied to detection of the number of the photons.

The present invention meets requirements for patentability including novelty, non-obviousness and usefulness.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

1. A carrier-modulated waveguide structure comprising:
a semiconductor bias unit which includes a first semiconductor layer, a bias intrinsic layer, and a second semiconductor layer, one side of the first semiconductor layer and one side of the second semiconductor layer correspondingly connected to two opposite sides of the bias intrinsic layer;
a light absorbing component arranged over a part of the first semiconductor layer, the bias intrinsic layer, and a part of the second semiconductor layer; and
a transporting control element having a main body and a plurality of carrier channels each spaced apart from both sides of adjacent carrier channels, one side of the main body disposed on the light absorbing component and another side of the main body extending to form the plurality of the carrier channels coupled to a plurality of light sensors one by one correspondingly;
wherein a sum of probabilities of carrier transporting of the carrier channels is 1.

2. The carrier-modulated waveguide structure as claimed in claim 1, wherein the first semiconductor layer and the second semiconductor layer are a p-type semiconductor layer and a n-type semiconductor layer respectively.

3. The carrier-modulated waveguide structure as claimed in claim 1, wherein the light absorbing component is a germanium component.

4. The carrier-modulated waveguide structure as claimed in claim 1, wherein a material for the transporting control element is selected from a p-type silicon material.

5. The carrier-modulated waveguide structure as claimed in claim 1, wherein the first semiconductor layer and the second semiconductor layer are respectively provided with a first protrusion arranged opposite to the bias intrinsic layer and a second protrusion disposed opposite to the bias intrinsic layer; the first protrusion and the second protrusion are combined with the bias intrinsic layer to form a stacked platform and the light absorbing component is disposed over the stacked platform; a first semiconductor doped layer and a second semiconductor doped layer are respectively connected to an outer side of the first semiconductor layer and an outer side of the second semiconductor layer.

6. The carrier-modulated waveguide structure as claimed in claim 1, wherein the light sensor includes:
a first electrode;
a first semiconductor bias layer disposed on one side of the first electrode and coupled to the first electrode;
a sensing intrinsic layer arranged at one side of the first semiconductor bias layer and connected to the first semiconductor bias layer;
a second semiconductor bias layer mounted to one side of the sensing intrinsic layer and connected to the sensing intrinsic layer; and
a second electrode disposed on one side of the second semiconductor bias layer and coupled to the second semiconductor bias layer;
wherein the sensing intrinsic layers of the light sensors are connected to the carrier channels.

7. The carrier-modulated waveguide structure as claimed in claim 1, wherein the carrier-modulated waveguide structure further includes a gate bias component which is electrically connected to and located over the light absorbing component and providing a gate bias to the light absorbing component.

8. The carrier-modulated waveguide structure as claimed in claim 1, wherein when a first light sensor of the light sensors receives a first incident photon absorbed by the light absorbing component from the transporting control element, the first light sensor drives a first carrier channel of the carrier channels and corresponding to the first light sensor to close and generates a light sensing signal within a first dead period.

9. The carrier-modulated waveguide structure as claimed in claim 1, wherein the light sensors provide a plurality of biases to the carrier channels correspondingly and the biases are corresponding to detection probabilities of the light sensors.

10. The carrier-modulated waveguide structure as claimed in claim 1, wherein when at least one light sensor of the light sensors receives at least one incident photon absorbed by the light absorbing component from the transporting control element, the at least one light sensor drives at least one carrier channel of the carrier channels corresponding to the at least one light sensor to close and generates a quantum strength signal according to the at least one incident photon within a first dead period; the number of the at least one incident photon determines strength of the quantum strength signal.
